(19) United States
(12) Patent Application Publication
(10) Pub. No.: US 2025/0089541 A1
(43) Pub. Date: Mar. 13, 2025

(54) DISPLAY DEVICE AND METHOD OF MANUFACTURING THE SAME

(71) Applicant: Samsung Display Co., Ltd., Yongin-si (KR)

(72) Inventors: KYUWON CHO, Yongin-si (KR); HYUNSEUNG LEE, Yongin-si (KR); YISEOP SHIM, Yongin-si (KR)

(73) Assignee: Samsung Display Co., Ltd., Yongin-si (KR)

(21) Appl. No.: 18/767,101

(22) Filed: Jul. 9, 2024

(30) Foreign Application Priority Data
Sep. 8, 2023 (KR) 10-2023-0119461

(51) Int. Cl. H10K 59/80; H10K 59/12; H10K 59/122; H10K 59/40; H10K 102/00

(52) U.S. Cl. CPC H10K 59/879; H10K 59/1201; H10K 59/122; H10K 59/40; H10K 59/873; H10K 59/8791; H10K 2102/351

(57) ABSTRACT

A display device includes a pixel definition layer provided with a pixel opening defined through the pixel definition layer, a light emitting element comprising a light emitting layer having at least a portion disposed in the pixel opening, a refractive pattern disposed on the light emitting element and overlapping the pixel opening, and a cover layer covering the refractive pattern and having a refractive index smaller than a refractive index of the refractive pattern. Grooves are defined in an upper surface of the refractive pattern, and each of the grooves has a diameter equal to or greater than about 50 nm and equal to or smaller than about 500 nm.

### CROSS REFERENCE TO RELATED APPLICATION(S)

This U.S. non-provisional patent application claims priority to and benefits of Korean Patent Application No. 10-2023-0119461 under 35 U.S.C. § 119, filed on Sep. 8, 2023 in the Korean Intellectual Property Office, the entire contents of which are incorporated herein by reference.

### BACKGROUND

### 1. Technical Field

The disclosure relates to a display device and a method of manufacturing the same. More particularly, the disclosure relates to a display device capable of improving a light emission efficiency and reducing a reflection of an external light and a method of manufacturing the display device.

### 2. Description of the Related Art

Various display devices applied to multimedia devices, such as televisions, mobile phones, tablet computers, and game devices, are being developed. The display devices include various optical functional layers to provide color images with excellent quality to a user.

Research efforts on a display device with a thin thickness are being conducted to implement various display devices, such as a display device with a curved surface, a rollable display device, and a foldable display device. A display device with a thin thickness may be implemented by reducing the number of the optical functional layers and including an optical functional layer with various functions.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The technical objectives to be achieved by the disclosure are not limited to those described herein, and other technical objectives that are not mentioned herein may be clearly understood by a person skilled in the art from this disclosure.

The disclosure provides a display device including a refractive pattern that improves a light emission efficiency and reducing a reflection of an external light.

The disclosure provides a method of manufacturing the display device, which is capable of simplifying the manufacturing processes to reduce a process time and cost.

Embodiments of the invention provide a display device including a pixel definition layer provided with a pixel opening defined through the pixel definition layer, a light emitting element including a light emitting layer, at least a portion of the light emitting layer being disposed in the pixel opening, a refractive pattern disposed on the light emitting element and overlapping the pixel opening, and a cover layer covering the refractive pattern and having a refractive index smaller than a refractive index of the refractive pattern. A plurality of grooves is defined in an upper surface of the refractive pattern, and each of the grooves has a diameter equal to or greater than about 50 nm and equal to or smaller than about 500 nm.

The refractive pattern further includes a lower surface opposite to the upper surface and a side surface connecting the upper surface and the lower surface.

The side surface includes a flat surface with a selectable inclination.

Each of the grooves has a depth equal to or greater than about 50 nm and equal to or smaller than about 500 nm.

The grooves are provided in three or more and nine or less per unit area of the upper surface, and the unit area is about 4 square micrometers.

The refractive index of the refractive pattern is equal to or greater than about 1.6.

The refractive pattern includes a photosensitive polymer.

The photosensitive polymer includes a block copolymer structural part.

The refractive pattern has a thickness equal to or greater than about 0.5 micrometers and equal to or smaller than about 1.5 micrometers.

The pixel opening includes a first pixel opening, a second pixel opening, and a third pixel opening, having different sizes from each other, and the refractive pattern includes a first refractive pattern corresponding to the first pixel opening, a second refractive pattern corresponding to the second pixel opening, and a third refractive pattern corresponding to the third pixel opening.

The display device further includes a polarizer disposed on the cover layer.

The display device further includes an encapsulation layer disposed on the light emitting element, and the refractive pattern is disposed on the encapsulation layer.

The display device further includes an input sensor disposed between the light emitting element and the refractive pattern. The input sensor includes a first insulating layer disposed on the encapsulation layer, a first conductive layer disposed on the first insulating layer, a second insulating layer disposed on the first insulating layer and covering the first conductive layer, and a second conductive layer disposed on the second insulating layer, and the refractive pattern is disposed on the second insulating layer.

The input sensor further includes a third insulating layer covering the second conductive layer and disposed on the second insulating layer, and the refractive pattern is disposed on the third insulating layer.

Embodiments of the invention provide a method of manufacturing a display device. The manufacturing method of the display device includes providing a pixel definition layer provided with a pixel opening defined through the pixel definition layer and a light emitting element including a light emitting layer having at least a portion disposed in the pixel opening, forming a preliminary refractive pattern including a photosensitive polymer on the light emitting element to overlap the pixel opening in a plan view, placing a mask including a grid part overlapping the preliminary refractive pattern in a plan view and provided with a plurality of holes defined through the grid part on the preliminary refractive pattern, exposing the grid part to an ultraviolet light, and coating a developing solution on the preliminary refractive pattern to form a refractive pattern including an upper surface in which a plurality of grooves having a diameter equal to or greater than about 50 nm and equal to or smaller than about 500 nm is formed.

An exposure amount of the ultraviolet light is equal to or greater than about one Joule (1 J).

A distance between a first hole and a second hole adjacent to the hole among the holes is equal to or greater than about 50 nm and equal to or smaller than about 500 nm.

The photosensitive polymer includes a block copolymer structural part.

The method further includes forming a cover layer covering the refractive pattern and having a refractive index smaller than a refractive index of the refractive pattern.

The grooves are provided in three or more and nine or less per unit area of the upper surface, and the unit area is about 4 square micrometers.

According to the above, the display device includes the refractive pattern provided with the grooves defined in the upper surface thereof, and thus, the light emission efficiency and the reflection of external light are improved.

According to the above, the manufacturing process of the refractive pattern is simplified, and thus, the process time and the process cost are reduced in the method of manufacturing the display device.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view of a display device according to an embodiment of the disclosure;

FIG. 2 is an exploded perspective view of a display device according to an embodiment of the disclosure;

FIG. 3 is a schematic cross-sectional view of a display device according to an embodiment of the disclosure;

FIG. 4A is a plan view of a display panel according to an embodiment of the disclosure;

FIG. 4B is a schematic cross-sectional view of a display panel according to an embodiment of the disclosure;

FIG. 5A is an enlarged plan view of an active area of a display panel according to an embodiment of the disclosure;

FIG. 5B is an enlarged plan view of a light emitting area defined in an active area of a display panel according to an embodiment of the disclosure;

FIG. 5C is an enlarged plan view of light emitting areas defined in an active area of a display panel according to an embodiment of the disclosure;

FIG. 5D is a schematic cross-sectional view of a display device taken along line I-I′ of FIG. 5A according to an embodiment of the disclosure;

FIG. 6 is a schematic cross-sectional view of a portion of a display device according to an embodiment of the disclosure;

FIG. 7 is a flowchart illustrating a method of manufacturing a display device according to an embodiment of the disclosure;

FIG. 8 is a schematic cross-sectional view illustrating a process of a method of manufacturing a display device according to an embodiment of the disclosure;

FIG. 9 is a schematic cross-sectional view illustrating a process of a method of manufacturing a display device according to an embodiment of the disclosure;

FIG. 10 is a schematic cross-sectional view illustrating a process of a method of manufacturing a display device according to an embodiment of the disclosure;

FIG. 11 is a schematic cross-sectional view illustrating a process of a method of manufacturing a display device according to an embodiment of the disclosure;

FIG. 12 is a schematic cross-sectional view illustrating a process of a method of manufacturing a display device according to an embodiment of the disclosure; and

FIG. 13 is a graph illustrating a variation of a light emission efficiency according to the number of grooves per unit area.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will be understood that when an element (or a region, a layer, a portion, or the like) is referred to as “being on”, “disposed on”, “connected to” or “coupled to” another element in the specification, it can be directly disposed on, connected or coupled to another element mentioned above, or intervening elements may be disposed therebetween. It will be understood that the terms “connected to” or “coupled to” may include a physical or electrical connection or coupling.

In the drawings, sizes, thicknesses, ratios, and dimensions of the elements may be exaggerated for ease of description and for clarity. Like numbers and/or reference characters refer to like elements throughout.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc. may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

As used herein, the singular forms, “a”, “an”, and “the” are intended to include the plural forms as well, unless the context clearly indicates otherwise.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “overlap”, “overlapping”, or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as “not overlapping” or “to not overlap” another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The phrase “in a plan view” means viewing the object from the top, and the phrase “in a schematic cross-sectional view” means viewing a cross-section of which the object is vertically cut from the side. Hence, the expression “in a plan view” used herein may mean that an object is viewed in the third direction DR3 from the top. The phrase “in a schematic cross-sectional view” means viewing a cross-section in the first direction DR1 or the second direction DR2 of which the object is vertically cut from the side. The direction DR3 also can be referred to as a “thickness direction”. A direction intersecting a first direction DR1 is referred to as a second direction DR2. A direction substantially perpendicular to a plane defined by the first and second directions DR1 and DR2 is referred to as a third direction DR3 or a “thickness direction”.

In case that an element is referred to as being “in contact” or “contacted” or the like to another element, the element may be in “electrical contact” or in “physical contact” with another element; or in “indirect contact” or in “direct contact” with another element.

A description that a component is “configured to” perform a specified operation may be defined as a case where the component is constructed and arranged with structural features that can cause the component to perform the specified operation.

Embodiments may be described and illustrated in the accompanying drawings in terms of functional blocks, units, and/or modules.

Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies.

In the case of the blocks, units, and/or modules being implemented by microprocessors or other similar hardware, they may be programmed and controlled using software (for example, microcode) to perform various functions discussed herein and may optionally be driven by firmware and/or software.

It is also contemplated that each block, unit, and/or module may be implemented by dedicated hardware, or as a combination of dedicated hardware to perform some functions and a processor (for example, one or more programmed microprocessors and associated circuitry) to perform other functions.

Each block, unit, and/or module of embodiments may be physically separated into two or more interacting and discrete blocks, units, and/or modules without departing from the scope of the disclosure.

Further, the blocks, units, and/or modules of embodiments may be physically combined into more complex blocks, units, and/or modules without departing from the scope of the disclosure.

Hereinafter, embodiments of the disclosure will be described with reference to accompanying drawings.

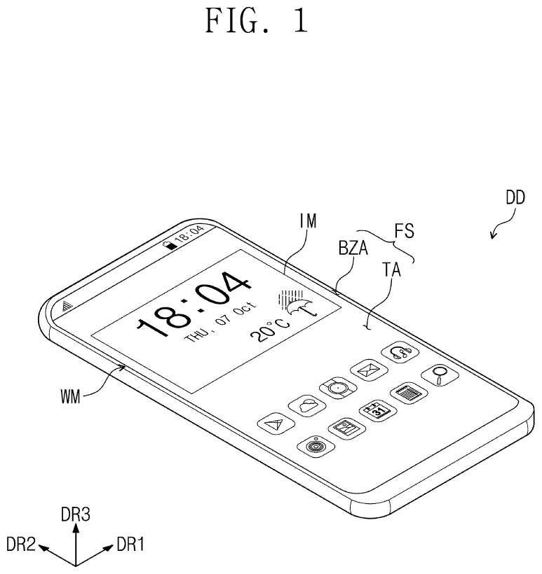

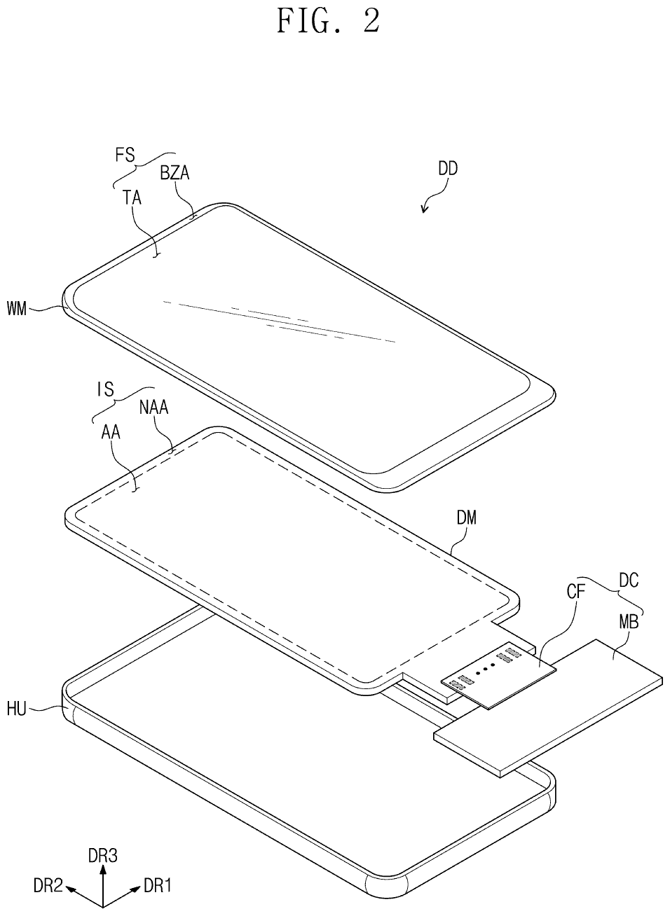

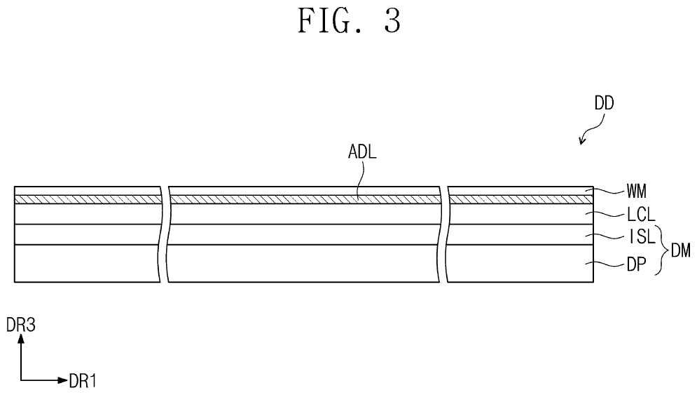

FIG. 1 is a perspective view of a display device DD according to an embodiment of the disclosure. FIG. 2 is an exploded perspective view of the display device DD according to an embodiment of the disclosure. FIG. 3 is a schematic cross-sectional view of the display device DD according to an embodiment of the disclosure.

Referring to FIG. 1, the display device DD may be activated in response to electrical signals. The display device DD may be applied to various embodiments. For example, the display device DD may be applied to an electronic device, such as a smart watch, a tablet computer, a notebook computer, a computer, and a smart television. In an embodiment, a smartphone will be described as a representative example of the display device DD.

The display device DD may display an image IM through a display surface FS, which is substantially parallel to each of the first direction DR1 and the second direction DR2, toward the third direction DR3. The image IM may include a video as well as a still image. FIG. 1 shows a clock widget and application icons as a representative example of the image IM. The display surface FS through which the image IM is displayed may correspond to a front surface of the display device DD and a front surface of a window WM.

In an embodiment, front (or upper) and rear (or lower) surfaces of each member of the display device DD may be defined with respect to a direction in which the image IM is displayed. The front and rear surfaces may be opposite to each other in the third direction DR3, and a normal line direction of each of the front and rear surfaces may be substantially parallel to the third direction DR3.

Referring to FIG. 2, the display device DD may include the window WM, a display module DM, a driving circuit DC, and a housing HU, or a combination thereof. In an embodiment, the window WM and the housing HU may be coupled to each other to provide an appearance of the display device DD.

The window WM may include an optically transparent insulating material. As an example, the window WM may include a glass or plastic material, or a combination thereof. The window WM may have a single-layer or multi-layer structure. As an example, the window WM may include plastic films coupled to each other by an adhesive or a glass substrate and a plastic film coupled to the glass substrate by an adhesive.

The front surface of the window WM may define a display surface FS of the display device DD as described above. A transmissive area TA may be an optically transparent area. For example, the transmissive area TA may be an area having a visible light transmittance of about 90% or more.

A bezel area BZA may be an area having a relatively lower transmittance as compared with the transmissive area TA. The bezel area BZA may define a shape of the transmissive area TA. The bezel area BZA may be disposed adjacent to the transmissive area TA and may surround the transmissive area TA.

The bezel area BZA may have a selectable color. The bezel area BZA may cover a peripheral area NAA of the display module DM to prevent the peripheral area NAA from being viewed from the outside. However, this is merely an example, and the bezel area BZA may be omitted from the window WM according to an embodiment of the disclosure.

The display module DM may display the image IM (refer to FIG. 1) and may sense an external input. The display module DM may include a front surface IS including an active area AA and the peripheral area NAA. The active area AA may be an area that is activated in response to electrical signals.

In an embodiment, the active area AA may be an area where the image IM (refer to FIG. 1) is displayed and the external input is sensed. The transmissive area TA may overlap at least a portion of the active area AA. For example, the transmissive area TA may overlap an entire surface or at least a portion of the active area AA.

Accordingly, a user may view the image IM (refer to FIG. 1) or may provide the external input through the transmissive area TA, however, this is merely an example. According to an embodiment, an area through which the image IM (refer to FIG. 1) is displayed and an area through which the external input is sensed may be separated from each other in the active area AA, and they should not be limited to an embodiment.

The peripheral area NAA may be covered by the bezel area BZA. The peripheral area NAA may be disposed adjacent to the active area AA. The peripheral area NAA may surround the active area AA. A driving circuit or a driving line to drive the active area AA may be disposed in the peripheral area NAA.

The driving circuit DC may include a flexible circuit board CF and a main circuit board MB. The flexible circuit board CF may be electrically connected to the display module DM. The flexible circuit board CF may connect the display module DM to the main circuit board MB. however, this is merely an example. According to an embodiment, the flexible circuit board CF may not be electrically connected to a separate circuit board, and the flexible circuit board CF may be a rigid substrate.

The flexible circuit board CF may be electrically connected to pads of the display module DM, which may be disposed in the peripheral area NAA. The flexible circuit board CF may provide electrical signals to the display module DM to drive the display module DM. The electrical signals may be generated by the flexible circuit board CF or the main circuit board MB.

The main circuit board MB may include various driving circuits to drive the display module DM or a connector to provide a power. The main circuit board MB may be electrically connected to the display module DM through the flexible circuit board CF.

The housing HU may be coupled with the window WM. The housing HU may be coupled with the window WM to provide a selectable inner space. The display module DM may be accommodated in the inner space.

The housing HU may have a material with a relatively high rigidity. For example, the housing HU may include a glass, plastic, or metal material or frames and/or plates of combinations thereof. The housing HU may stably protect the components of the display device DD, which may be accommodated in the inner space, from external impacts.

FIG. 3 is a schematic cross-sectional view of the display device DD according to an embodiment of the disclosure. In FIG. 3, the display device DD is simply shown to illustrate a stacking relationship of functional panels and/or functional parts constituting the display device DD.

The display device DD may include the display module DM, a light control layer LCL, and the window WM. The display module DM may include a display panel DP and an input sensor ISL. According to an embodiment, the input sensor ISL may be omitted.

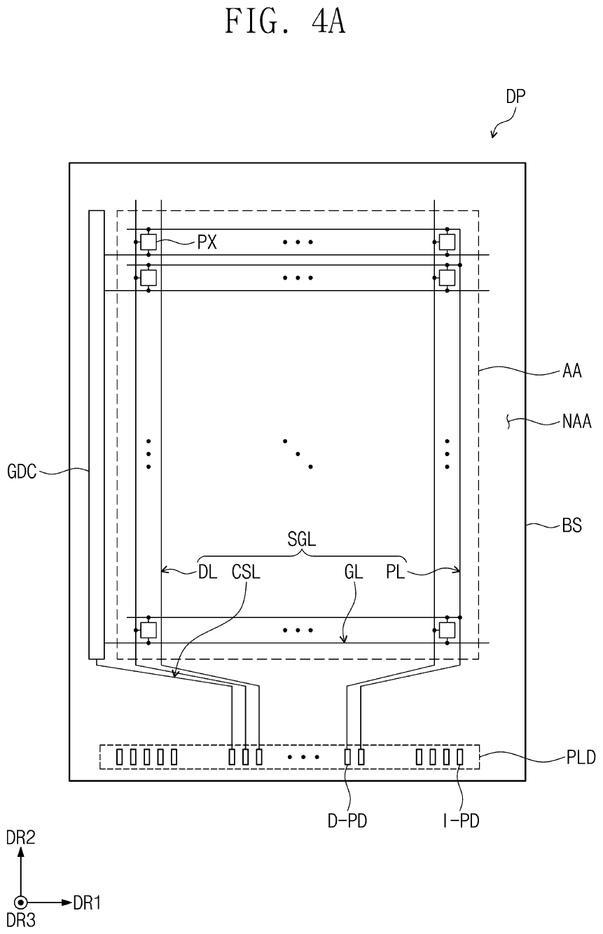

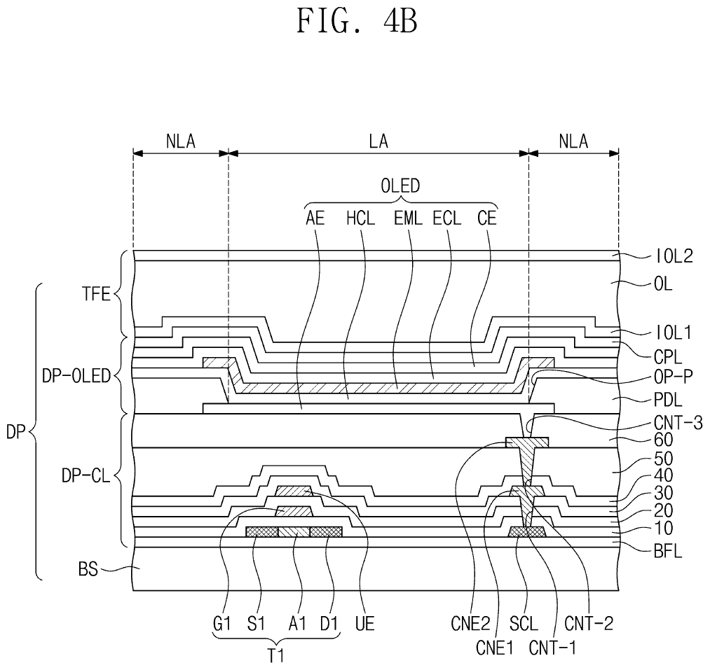

The display panel DP may generate the image. The display panel DP may include pixels PX (refer to FIG. 4A). The display panel DP may be a light-emitting type display panel that includes a light emitting element as its display element, however, it should not be particularly limited. For instance, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot, a quantum rod, or an inorganic LED, or a combination thereof. Hereinafter, the organic light emitting display panel will be described as a representative example of the display panel DP.

The input sensor ISL may be disposed on the display panel DP. The input sensor ISL may obtain coordinate information of the external input, e.g. a touch event. The input sensor ISL may sense the external input by a capacitive method.

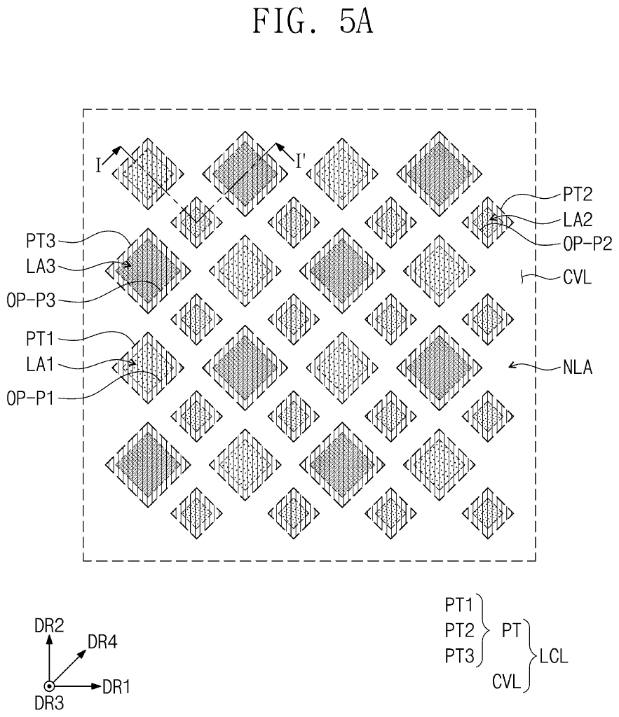

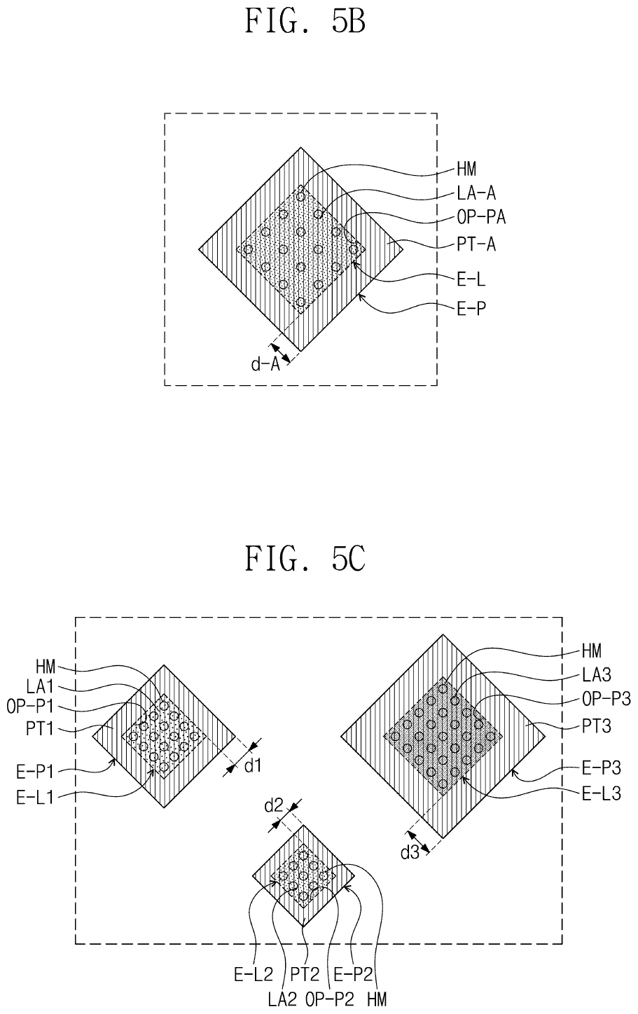

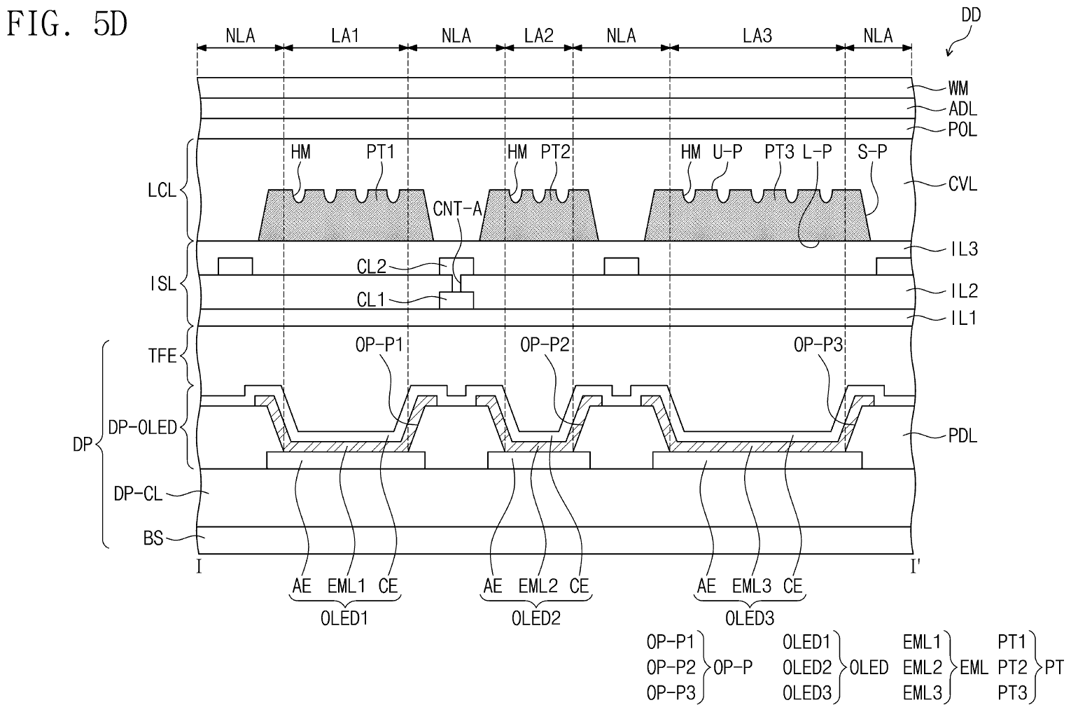

The light control layer LCL may be disposed on the input sensor ISL. The light control layer LCL may include a refractive pattern PT and a cover layer CVL, which are described later with reference to FIGS. 5A and 5B. The refractive pattern PT and the cover layer CVL may have different refractive indices from each other.

The light control layer LCL may control a path of a light (hereinafter, referred to as a source light) generated by the display panel DP. In addition, the light control layer LCL may reduce a reflectance with respect to a natural light (or a sunlight) incident thereto from above the window WM. This will be described in detail later.

The window WM may be disposed on the light control layer LCL. The window WM may be coupled with the light control layer LCL by a window adhesive layer ADL. The window adhesive layer ADL may be a pressure sensitive adhesive (PSA) film or an optically clear adhesive (OCA).

FIG. 4A is a plan view of the display panel DP according to an embodiment of the disclosure. FIG. 4B is a schematic cross-sectional view of the display panel DP according to an embodiment of the disclosure.

Referring to FIG. 4A, the display panel DP may include a base layer BS that includes the active area AA and the peripheral area NAA described with described with reference to FIG. 2.

The display panel DP may include the pixels PX disposed in the active area AA and signal lines SGL electrically connected to the pixels PX. The display panel DP may include a driving circuit GDC and a pad part PLD, which may be disposed in the peripheral area NAA.

The pixels PX may be arranged in the first direction DR1 and the second direction DR2. The pixels PX may include pixel rows extending in the first direction DR1 and arranged in the second direction DR2 and pixel columns extending in the second direction DR2 and arranged in the first direction DR1.

The signal lines SGL may include gate lines GL, data lines DL, a power line PL, and a control signal line CSL. Each of the gate lines GL may be electrically connected to a corresponding pixel among the pixels PX, and each of the data lines DL may be electrically connected to a corresponding pixel among the pixels PX. The power line PL may be electrically connected to the pixels PX. The control signal line CSL may be electrically connected to the driving circuit GDC and may provide control signals to the driving circuit GDC.

The driving circuit GDC may include a gate driving circuit. The gate driving circuit may generate gate signals and may sequentially output the gate signals to the gate lines GL. The gate driving circuit may further output other control signals to a pixel driving circuit.

The pad part PLD may be electrically connected to the flexible circuit board CF describe with reference to FIG. 2. The pad part PLD may include pixel pads D-PD and input pads I-PD.

The pixel pads D-PD may be pads to connect the flexible circuit board CF(refer to FIG. 2) to the display panel DP. Each of the pixel pads D-PD may be electrically connected to a corresponding signal line among the signal lines SGL. The pixel pads D-PD may be electrically connected to corresponding pixels PX via the signal lines SGL. In addition, the driving circuit GDC may be electrically connected to a pixel pad among the pixel pads D-PD.

The input pads I-PD may be pads to connect the flexible circuit board CF(refer to FIG. 2) to the input sensor ISL (refer to FIG. 3). FIG. 4A shows the structure in which the input pads I-PD may be disposed in the display panel DP, however, the disclosure should not be limited as described herein. According to an embodiment, the input pads I-PD may be disposed in the input sensor ISL(refer to FIG. 3) and may be electrically connected to a different circuit board from a circuit board to which the pixel pads D-PD are electrically connected.

Referring to FIG. 4B, the display panel DP may include the base layer BS, a circuit element layer DP-CL, a display element layer DP-OLED, and an encapsulation layer TFE.

The base layer BS may include a synthetic resin layer. The base layer BS may be a glass substrate, a metal substrate, or an organic/inorganic composite substrate. As an example, the base layer BS may be a silicon substrate containing silicon. The base layer BS may be a silicon wafer.

At least one inorganic layer may be disposed on an upper surface of the base layer BS. A buffer layer BFL may increase an adhesive force between the base layer BS and a semiconductor pattern. The buffer layer BFL may include a silicon oxide layer and a silicon nitride layer, or a combination thereof, and the silicon oxide layer and the silicon nitride layer may be alternately stacked each other.

The display panel DP may include insulating layers, a semiconductor pattern, a conductive pattern, and a signal line. An insulating layer, a semiconductor layer, and a conductive layer may be formed by a coating or depositing process. The insulating layer, the semiconductor layer, and the conductive layer subsequently may be selectively patterned through several photolithography processes. Accordingly, the semiconductor pattern, the conductive pattern, and the signal line included in the circuit element layer DP-CL and the display element layer DP-OLED may be formed.

The semiconductor pattern may be disposed on the buffer layer BFL. The semiconductor pattern may include polysilicon, however, it should not be limited as described herein. According to an embodiment, the semiconductor pattern may include amorphous silicon or metal oxide, or a combination thereof.

FIG. 4B shows a portion of the semiconductor pattern, and the semiconductor pattern may be further disposed in light emitting areas LA1, LA2, and LA3 (refer to FIGS. 5A and 5B) described later. The semiconductor pattern may be arranged with a selected rule over the light emitting areas. The semiconductor pattern may have different electrical properties depending on whether it is doped or not or whether it is doped with an N-type dopant or a P-type dopant. The semiconductor pattern may include a first region having a relatively high doping concentration and a second region having a relatively low doping concentration. The first region may be doped with the N-type dopant or the P-type dopant. A P-type transistor may include a doped region doped with the P-type dopant.

The first region may have a conductivity greater than that of the second region and may substantially serve as an electrode or a signal line. The second region may substantially correspond to an active (or a channel) of a transistor. In other words, a portion of the semiconductor pattern may be the active of the transistor, another portion of the semiconductor pattern may be a source or a drain of the transistor, and another portion of the semiconductor pattern may be a conductive area.

As shown in FIG. 4B, a source Si, an active A1, and a drain D1 of a transistor T1 may be formed from the semiconductor pattern. FIG. 4B shows a portion of a signal transmission line SCL formed from the semiconductor pattern. Although not shown in figures, the signal transmission line SCL may be electrically connected to the drain D1 of the transistor T1 in a plan view.

First, second, third, fourth, fifth, and sixth insulating layers 10, 20, 30, 40, 50, and 60 may be disposed on the buffer layer BFL. Each of the first insulating layer 10 to the sixth insulating layer 60 may be an inorganic layer or an organic layer. A gate G1 may be disposed on the first insulating layer 10. An upper electrode UE may be disposed on the second insulating layer 20. A first connection electrode CNE1 may be disposed on the third insulating layer 30. The first connection electrode CNE1 may be electrically connected to the signal transmission line SCL via a contact hole CNT-1 defined through the first to third insulating layers 10 to 30. The fourth insulating layer 40 and the fifth insulating layer 50 may be disposed on the third insulating layer 30. According to an embodiment, each of the fourth insulating layer 40 and the fifth insulating layer 50 may be an organic layer.

A second connection electrode CNE2 may be disposed on the fifth insulating layer 50. The second connection electrode CNE2 may be electrically connected to the first connection electrode CNE1 via a contact hole CNT-2 defined through the fourth insulating layer 40 and the fifth insulating layer 50.

The display element layer DP-OLED may be disposed on the circuit element layer DP-CL. According to an embodiment, the display element layer DP-OLED may include a light emitting element OLED, a pixel definition layer PDL, and a capping layer CPL.

The light emitting element OLED may be disposed on the sixth insulating layer 60. According to an embodiment, the light emitting element OLED may include a first electrode AE, a hole control layer HCL, a light emitting layer EML, an electron control layer ECL, and a second electrode CE.

The first electrode AE may be disposed on the sixth insulating layer 60. The first electrode AE may be electrically connected to the second connection electrode CNE2 via a contact hole CNT-3 defined through the sixth insulating layer 60. The pixel definition layer PDL may be disposed on the sixth insulating layer 60. A pixel opening OP-P may be defined through the pixel definition layer PDL. At least a portion of the first electrode AE may be exposed through the pixel opening OP-P of the pixel definition layer PDL. In an embodiment, a light emitting area LA may be defined to correspond to the portion of the first electrode AE exposed through the pixel opening OP-P. A non-light-emitting area NLA may correspond to an area of the active area AA(refer to FIG. 2) except the light emitting area LA.

The pixel definition layer PDL may have a light absorbing material. The pixel definition layer PDL may include a black coloring agent. The black coloring agent may include a black dye or a black pigment. The black coloring agent may include a metal material, such as carbon black, chromium, and an oxide thereof.

The hole control layer HCL may be disposed on the first electrode AE. The hole control layer HCL may be commonly disposed in the light emitting area LA and the non-light-emitting area NLA. The hole control layer HCL may include a hole transport layer and may further include a hole injection layer.

The light emitting layer EML may be disposed on the hole control layer HCL. The light emitting layer EML may be disposed in an area corresponding to the pixel opening OP-P. For example, the light emitting layer EML may be disposed to correspond to the light emitting area LA.

The electron control layer ECL may be disposed on the light emitting layer EML. The electron control layer ECL may include an electron transport layer and may further include an electron injection layer. The second electrode CE may be disposed on the electron control layer ECL. The electron control layer ECL and the second electrode CE may be commonly disposed over the light emitting area LA and the non-light-emitting area NLA.

The capping layer CPL may be disposed on the second electrode CE. The capping layer CPL may be commonly disposed over the light emitting area LA and the non-light-emitting area NLA.

According to an embodiment, the capping layer CPL may include an inorganic material. The capping layer CPL may be formed through a sputtering deposition process.

The capping layer CPL may cover the second electrode CE and thus may protect the second electrode CE and the light emitting layer EML from external moisture and contaminants. In addition, a light totally reflected at an interface between the second electrode CE and the capping layer CPL may be reduced by adjusting a refractive index and a thickness of the capping layer CPL.

The encapsulation layer TFE may be disposed on the display element layer DP-OLED. The encapsulation layer TFE may encapsulate the display element layer DP-OLED. The encapsulation layer TFE may include a single layer or multiple layers stacked each other. The encapsulation layer TFE may include at least one organic layer.

According to an embodiment, the encapsulation layer TFE may include a first inorganic layer IOL1, an organic layer OL, and a second inorganic layer IOL2. The first inorganic layer IOL1 may be disposed on the capping layer CPL. The organic layer OL may be disposed on the first inorganic layer IOL1. The second inorganic layer IOL2 may be disposed on the organic layer OL and may cover the organic layer OL.

The first inorganic layer IOL1 and the second inorganic layer IOL2 may protect the display element layer DP-OLED from moisture and oxygen, and the organic layer OL may protect the display element layer DP-OLED from a foreign substance such as dust particles.

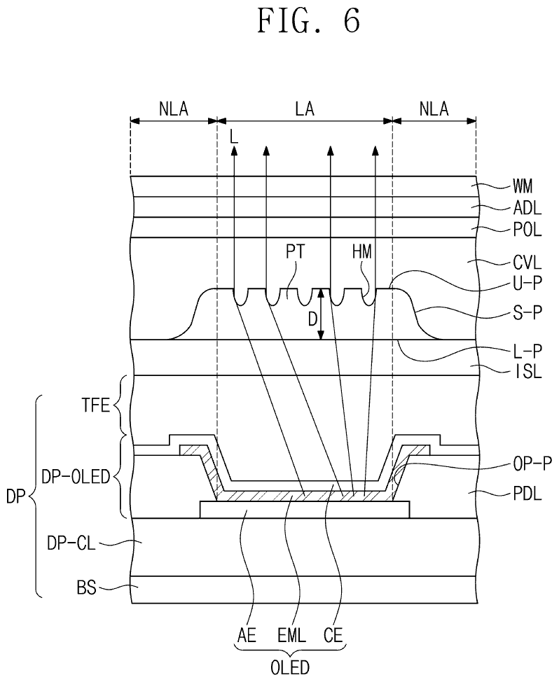

FIG. 5A is an enlarged plan view of the active area of the display panel according to an embodiment of the disclosure. FIG. 5B is an enlarged plan view of a light emitting area defined in the active area of the display panel according to an embodiment of the disclosure. FIG. 5C is an enlarged plan view of light emitting areas defined in the active area of the display panel according to an embodiment of the disclosure. FIG. 5D is a schematic cross-sectional view of the display device taken along line I-I′ of FIG. 5A according to an embodiment of the disclosure. FIG. 6 is a schematic cross-sectional view of a portion of the display device according to an embodiment of the disclosure.

FIG. 5A is a plan view illustrating a relationship between the light control layer LCL and the light emitting areas LA1, LA2, and LA3 when viewed from a direction facing the front surface of the display device DD. FIGS. 5B and 5C are enlarged plan views of a portion of the light control layer LCL and the light emitting areas LA1, LA2, and LA3.

Referring to FIGS. 4B and 5A, the pixel opening OP-P may include a first pixel opening OP-P1, a second pixel opening OP-P2, and a third pixel opening OP-P3, having different sizes from each other. The size of the first pixel opening OP-P1 may be greater than the size of the second pixel opening OP-P2 in a plan view, and may be smaller than the size of the third pixel opening OP-P3 in a plan view.

Referring to FIGS. 5A and 5D, the light emitting layer EML may include a first light emitting layer EML1, a second light emitting layer EML2, and a third light emitting layer EML3. An area where the first pixel opening OP-P1 may overlap the first light emitting layer EML1 in a plan view may be defined as a first light emitting area LA1. An area where the second pixel opening OP-P2 may overlap the second light emitting layer EML2 in a plan view may be defined as a second light emitting area LA2. An area where the third pixel opening OP-P3 may overlap the third light emitting layer EML3 in a plan view may be defined as a third light emitting area LA3.

The first and third light emitting areas LA1 and LA3 may be alternately arranged with each other in the first direction DR1 in a plan view. The second light emitting areas LA2 may be arranged in a different pixel row from the first and third light emitting areas LA1 and LA3 in a plan view, and the second light emitting areas LA2 may be arranged in the same pixel row along the first direction DR1 in a plan view. The first and second light emitting areas LA1 and LA2 may be alternately arranged with each other in a fourth direction DR4 crossing the first and second directions DR1 and DR2. The second and third light emitting areas LA2 and LA3 may be alternately arranged with each other in the fourth direction DR4. However, the embodiment is not limited to the arrangement of the first, second, and third light emitting areas LA1, LA2, and LA3 as described herein.

FIG. 5B is an enlarged plan view illustrating a pattern PT-A among first, second, and third patterns PT1, PT2, and PT3 shown in FIG. 5A and a light emitting area LA-A corresponding to the pattern PT-A among the first, second, and third light emitting areas LA1, LA2, and LA3. Hereinafter, descriptions of the pattern PT-A described with reference to FIG. 5B may be applied to the first, second, and third patterns PT1, PT2, and PT3.

Referring to FIG. 5B, a size of the pattern PT-A may be greater than a size of the corresponding light emitting area LA-A in a plan view. Accordingly, an edge E-P of the pattern PT-A may surround an edge E-L of the corresponding light emitting area LA-A in a plan view. In this case, the edge E-P of the pattern PT-A may be spaced apart from the edge E-L of the corresponding light emitting area LA-A by a selectable distance d-A (hereinafter, referred to as a separation distance).

Referring to FIGS. 4B and 5B, the edge E-P of the pattern PT-A may be defined as an outermost portion of pattern PT-A, which may contact a third insulating layer IL3 (refer to FIG. 5D) of the input sensor ISL. In the disclosure, the edge E-L of the light emitting area LA-A may be defined as an outermost portion of the first electrode AE exposed through a pixel opening OP-PA of the pixel definition layer PDL without being covered by the pixel definition layer PDL.

The separation distance d-A between the edge E-P of the pattern PT-A and the edge E-L of the light emitting area LA-A may be equal to or greater than about 0.5 micrometers.

For example, the pattern PT-A may entirely cover the corresponding light emitting area LA-A in a plan view and may have the size greater than that of the corresponding light emitting area LA-A in a plan view, and thus, a light emitted from the light emitting element OLED (refer to FIG. 4B) toward a side surface direction may pass through the pattern PT-A. Accordingly, the pattern PT-A may output the light traveling in the side surface direction to substantially the same direction as the third direction DR3, thus the light emission efficiency of the display device may be improved. This will be described in detail later.

FIG. 5C is an enlarged plan view illustrating each of the first, second, and third patterns PT1, PT2, and PT3 shown in FIG. 5A.

A separation distance between an edge E-P1 of the first pattern PT1 and an edge E-L1 of the first light emitting area LA1 in a plan view is referred to as a first distance d1. A separation distance between an edge E-P2 of the second pattern PT2 and an edge E-L2 of the second light emitting area LA2 in a plan view is referred to as a second distance d2. A separation distance between an edge E-P3 of the third pattern PT3 and an edge E-L3 of the third light emitting area LA3 in a plan view is referred to as a third distance d3.

The first distance d1, the second distance d2, and the third distance d3 may have different values from each other based on characteristics of lights emitted from the first, second, and third light emitting areas LA1, LA2, and LA3.

Referring to FIG. 5D, the display device DD may include the display panel DP, the input sensor ISL, the light control layer LCL, the window adhesive layer ADL, and the window WM, and the display panel DP may include the base layer BS, the circuit element layer DP-CL, the display element layer DP-OLED, and the encapsulation layer TFE.

FIG. 5D schematically illustrates each of the base layer BS, the circuit element layer DP-CL, and the encapsulation layer TFE as a single layer. FIG. 4B illustrates the display element layer DP-OLED comprising the pixel definition layer PDL, and a light emitting element OLED comprising the first electrode AE, the light emitting layer EML, and the second electrode CE. In FIG. 5D, the same/similar reference numerals denote the same/similar elements in FIGS. 1 to 4B, and thus, detailed descriptions of the same/similar elements will be omitted.

The light emitting element OLED may include the light emitting layer EML having at least a portion disposed in the pixel opening OP-P. The light emitting element OLED may include the first electrode AE, the light emitting layer EML disposed on the first electrode AE and including at least the portion disposed in the pixel opening OP-P, and the second electrode CE disposed on the light emitting layer EML. The light emitting element OLED may be provided in plural, and the light emitting elements OLED may include a first light emitting element OLED1, a second light emitting element OLED2, and a third light emitting element OLED3.

The first light emitting element OLED1 may include the first electrode AE exposed through the first pixel opening OP-P1, the first light emitting layer EML1 disposed on the first electrode AE and emitting a first color light, and the second electrode CE disposed on the first light emitting layer EML1. At least a portion of the first light emitting layer EML1 may be disposed in the first pixel opening OP-P1. The first pixel opening OP-P1 may define the first light emitting area LA1.

The second light emitting element OLED2 may include the first electrode AE exposed through the second pixel opening OP-P2, the second light emitting layer EML2 disposed on the first electrode AE and emitting a second color light, and the second electrode CE disposed on the second light emitting layer EML2. At least a portion of the second light emitting layer EML2 may be disposed in the second pixel opening OP-P2. The second pixel opening OP-P2 may define the second light emitting area LA2.

The third light emitting element OLED3 may include the first electrode AE exposed through the third pixel opening OP-P3, the third light emitting layer EML3 disposed on the first electrode AE and emitting a third color light, and the second electrode CE disposed on the third light emitting layer EML3. At least a portion of the third light emitting layer EML3 may be disposed in the third pixel opening OP-P3. The third pixel opening OP-P3 may define the third light emitting area LA3.

The first light emitting layer EML1 included in the first light emitting element OLED1 may emit the first color light. The second light emitting layer EML2 included in the second light emitting element OLED2 may emit the second color light. The third light emitting layer EML3 included in the third light emitting element OLED3 may emit the third color light. The first, second, and third color lights may have different colors from each other. As an example, the first color light from the first light emitting area LA1 may be a red light, the second color light from the second light emitting area LA2 may be a green light, and the third color light from the third light emitting area LA3 may be a blue light. However, the disclosure should not be limited as described herein, and the first, second, and third color lights may be selected as combinations of three color lights that produce a white color light in case that they are being mixed. According to an embodiment, the first, second, and third color lights may have a same color.

The display device DD may further include the input sensor ISL disposed between the light emitting element OLED and the refractive pattern PT. The input sensor ISL may be disposed directly on the encapsulation layer TFE. The input sensor ISL may include a first insulating layer IL1, a first conductive layer CL1, a second insulating layer IL2, a second conductive layer CL2, and the third insulating layer IL3. The first insulating layer IL1 may be disposed on the encapsulation layer TFE. The first conductive layer CL1 may be disposed on the first insulating layer IL1. The second insulating layer IL2 may be disposed on the first insulating layer IL1 and may cover the first conductive layer CL1. The second conductive layer CL2 may be disposed on the second insulating layer IL2. The second conductive layer CL2 may be electrically connected to the first conductive layer CL1 via a contact hole CNT-A defined through the second insulating layer IL2. The third insulating layer IL3 may be disposed on the second insulating layer IL2 and may cover the second conductive layer CL2.

Each of the first insulating layer IL1, the second insulating layer IL2, and the third insulating layer IL3 may include at least one of an inorganic material and an organic material, or a combination thereof. Each of the first conductive layer CL1 and the second conductive layer CL2 may have a conductivity and may have a single-layer or multi-layer structure.

At least one of the first conductive layer CL1 and the second conductive layer CL2 may be provided as mesh lines in a plan view. The mesh lines may not overlap the light emitting layer EML in a plan view. Accordingly, even though the input sensor ISL is formed directly on the display panel DP, the light emitted from the light emitting element OLED may be provided to the user without being interfered by the input sensor ISL.

The light control layer LCL may be disposed on the light emitting element OLED. The light control layer LCL may be disposed on the input sensor ISL. The light control layer LCL may include the refractive pattern PT and the cover layer CVL.

The refractive pattern PT may be disposed above the light emitting element OLED and may overlap the pixel opening OP-P. The refractive pattern PT may be disposed above the encapsulation layer TFE. The refractive pattern PT may be disposed on the input sensor ISL. The refractive pattern PT may be disposed on the third insulating layer IL3. The refractive pattern PT may include the first pattern PT1, the second pattern PT2, and the third pattern PT3. The first pattern PT1 may overlap the first pixel opening OP-P1, the second pattern PT2 may overlap the second pixel opening OP-P2, and the third pattern PT3 may overlap the third pixel opening OP-P3. The first pattern PT1, the second pattern PT2, and the third pattern PT3 may have different sizes from each other in a plan view. The first pattern PT1 may entirely overlap the first light emitting area LA1, the second pattern PT2 may entirely overlap the second light emitting area LA2, and the third pattern PT3 may entirely overlap the third light emitting area LA3.

As shown in FIG. 5A, the first, second, and third patterns PT1, PT2, and PT3 may have arrangements corresponding to arrangements of the first, second, and third light emitting areas LA1, LA2, and LA3. As an example, the first and third patterns PT1 and PT3 may be alternately arranged in the first direction DR1 in a plan view. The second patterns PT2 may be spaced apart from the first and third patterns PT1 and PT3 in the second direction DR2, and the second patterns PT2 may be arranged in the first direction DR1. The first and second patterns PT1 and PT2 may be alternately arranged in the fourth direction DR4. The second and third patterns PT2 and PT3 may be alternately arranged in the fourth direction DR4. However, the arrangements of the first, second, and third patterns PT1, PT2, and PT3 should not be limited as described herein, and may be changed depending on the arrangements of the first, second, and third light emitting areas LA1, LA2, and LA3.

Each of the first, second, and third patterns PT1, PT2, and PT3 may have a trapezoidal shape when viewed in a schematic cross-sectional view. Each of the first, second, and third patterns PT1, PT2, and PT3 may include an upper surface U-P, a lower surface L-P opposite to the upper surface U-P and disposed closer to the display panel DP than the upper surface U-P is, and a side surface S-P connecting the upper surface U-P and the lower surface L-P. In this case, the lower surface L-P may be in contact with the third insulating layer IL3.

Multiple grooves HM may be defined in the upper surface U-P of the refractive pattern PT. The grooves HM may modify paths of lights L (refer to FIG. 6) emitted from the light emitting layer EML to a direction that is substantially the same as the third direction DR3. For example, the lights L (refer to FIG. 6) emitted from the light emitting layer EML may travel in substantially the same direction as the third direction DR3 after passing through the grooves HM, and thus, the light emission efficiency of the display device DD may be improved. In case that the grooves are defined in the upper surface U-P of the refractive pattern PT, the external light may not be totally reflected to the third direction DR3 and may be scattered to other directions, and the reflection of the external light may be improved.

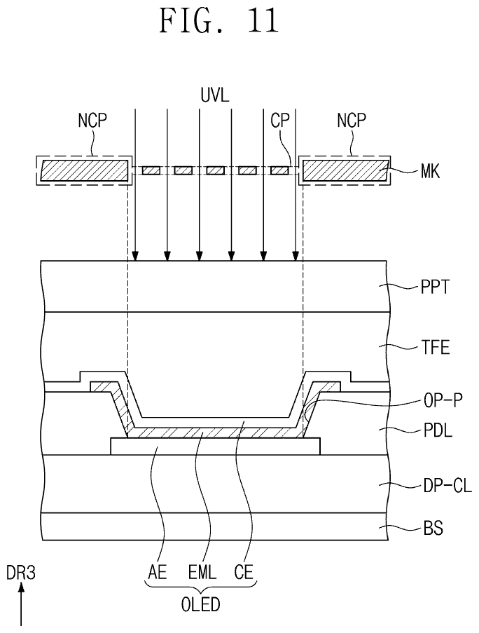

Each of the grooves HM may have a diameter equal to or greater than about 50 nm and equal to or smaller than about 500 nm. The grooves HM may have different diameters from each other. As an example, some of the grooves HM may have a diameter of about 100 nm. In a case where the diameter of the groove HM is smaller than about 50 nm, the lights L (refer to FIG. 6) emitted from the light emitting layer EML may contact the groove HM relatively few times since the diameter is small, and thus, it is difficult to improve the light emission efficiency of the display device DD, and the total reflection of the external light may not be effectively prevented. In a case where the diameter of the groove HM is greater than about 500 nm, the number of the grooves HM defined in the upper surface U-P is reduced. Accordingly, it is difficult to improve the light emission efficiency of the display device DD, and the total reflection of the external light may not be effectively prevented. Each of the grooves HM may have a depth equal to or greater than about 50 nm and equal to or smaller than about 500 nm. As an example, the depth of the groove HM may be about 105 nm. In a case where the depth of the groove HM is smaller than about 50 nm, the lights L (refer to FIG. 6) emitted from the light emitting layer EML may contact the groove HM relatively few times. Therefore, it is difficult to improve the light emission efficiency of the display device DD, and the total reflection of the external light may not be effectively prevented. In a case where the depth of the groove HM is greater than about 500 nm, an ultraviolet light UVL (refer to FIG. 11) used in a manufacturing process of the display device DD may penetrate the refractive pattern PT due to its strong intensity, and the difficulty of the manufacturing process may increase.

The number of grooves HM defined in the upper surface U-P may be three or more and nine or less per unit area of the upper surface U-P. The unit area may be about 4 square micrometers. The unit area may be an area defined by a square having each of horizontal and vertical sides with a length of about 2 micrometers. Sixteen grooves HM may be defined in the upper surface U-P of the first pattern PT1. Nine grooves HM may be defined in the upper surface U-P of the second pattern PT2. Twenty-five grooves HM may be defined in the upper surface U-P of the third pattern PT3. In a case where two or less grooves HM are defined in the upper surface U-P per unit area, the light emission efficiency may not be sufficiently improved since the number of grooves HM is too small. In a case where ten or more grooves HM are defined in the upper surface U-P per unit area, two or more grooves HM adjacent to each other may overlap each other, and consequently, the diameter of the groove HM may be greater than about 500 nm.

The side surface S-P of the refractive pattern PT may include a flat surface with a selectable inclination. The groove HM may not be defined in the side surface S-P of the refractive pattern PT.

The lower surface L-P of the refractive pattern PT may be directly in contact with an upper surface of the encapsulation layer TFE. The lower surface L-P of the refractive pattern PT may be directly in contact with an upper surface of the input sensor ISL. The lower surface L-P of the refractive pattern PT may be directly in contact with an upper surface of the third insulating layer IL3.

The refractive pattern PT may include a photosensitive polymer. The photosensitive polymer may include repeating units of the following formulas 1 to 5. Formula 1

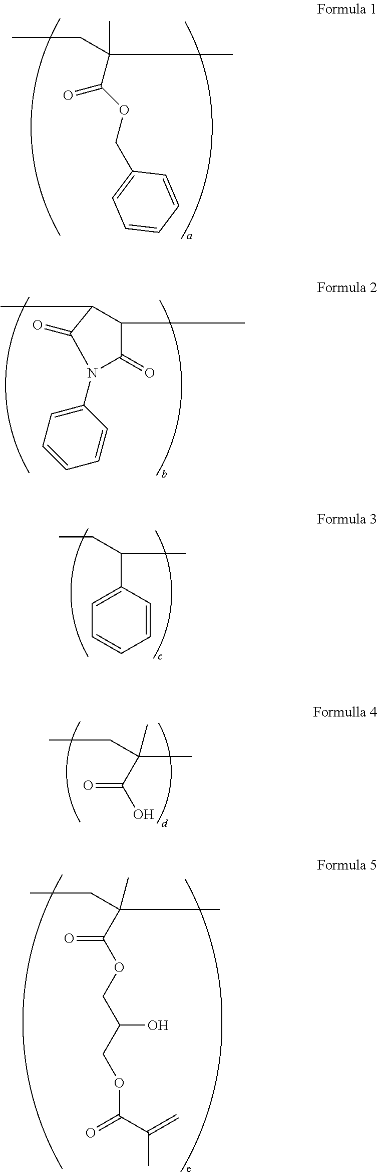

In Formulas 1 to 5, a, b, c, d, and e are each independently an integer from 1 to 1000. The photosensitive polymer may further include a block copolymer structural part. As an example, the block copolymer structural part may include polystyrene block methyl methacrylate. The refractive pattern PT may further include a high refractive index monomer. As an example, the refractive pattern PT may include an acrylic resin.

The cover layer CVL may be disposed on the second insulating layer IL2. The cover layer CVL may be in contact with the upper surface U-P and the side surface S-P of the refractive pattern PT and may cover the refractive pattern PT.

The cover layer CVL may be a layer obtained by dispersing a dye and/or a pigment in a polymer resin. The dye and/or the pigment included in the cover layer CVL may be a material that transmits only light in a selected wavelength range among the lights emitted from the light emitting elements OLED1, OLED2, and OLED3.

The dye and the pigment may absorb a light in a wavelength range of about 490 nm to about 505 nm and a light in a wavelength range of about 585 nm to about 600 nm and may transmit lights in wavelengths other than the above range. As the dye and the pigment included in the cover layer CVL absorb the lights in the selected wavelength range and transmit the lights in wavelengths other than the above range, the reflection of the external light may be prevented, and the color of the light emitted from the display panel DP may be controlled.

The cover layer CVL may further include an adhesive material. Accordingly, the window adhesive layer ADL disposed on the cover layer CVL and attaching the window WM may be omitted.

The cover layer CVL may be patterned by a photolithography process or an inkjet printing process.

The refractive pattern PT may have a refractive index greater than a refractive index of the cover layer CVL. The refractive index of the refractive pattern PT may be equal to or greater than about 1.6. The refractive index of the cover layer CVL may be equal to or smaller than about 1.5. Since the cover layer CVL having the refractive index smaller than the refractive index of the refractive pattern PT covers the refractive pattern PT, the light emission efficiency may be further improved.

The refractive pattern PT may have a thickness D equal to or greater than about 0.5 micrometers and equal to or smaller than about 1.5 micrometers. For example, a distance in the third direction DR3 between the upper surface U-P and the lower surface L-P of the refractive pattern PT may be equal to or greater than about 0.5 micrometers and equal to or smaller than about 1.5 micrometers.

A polarizer POL may be disposed on the cover layer CVL included in the light control layer LCL. The polarizer POL may reduce the reflectance of the external light incident thereto from the outside. The polarizer POL may include at least one of a retarder, a polarizer, a polarizing film, and a polarizing filter. However, the polarizer POL should not be limited as described herein. As an example, the polarizer POL may include a color filter.

FIG. 6 is an enlarged cross-sectional view illustrating any one of the first, second, and third patterns PT1, PT2, and PT3 shown in FIG. 5C. Hereinafter, a change in path of the light due to a difference in refractive index between the refractive pattern PT and the cover layer CVL will be described with reference to FIG. 6.

The light control layer LCL may include the refractive pattern PT having the high refractive index and the cover layer CVL having the low refractive index and may transmit the light emitted from the light emitting element OLED, and thus, the light emission efficiency of the display panel DP may be improved.

In detail, the light L traveling in the side surface direction among the lights emitted from the light emitting element OLED may be refracted by the groove HM defined in the upper surface U-P of the refractive pattern PT, and thus, the path of the light L traveling in a direction inclined with respect to the third direction DR3 at a selectable angle may be changed to allow the light L traveling in the direction inclined with respect to the third direction DR3 to travel in substantially the same direction as the third direction DR3. Accordingly, a light emission efficiency in a front surface direction of each of the light emitting elements OLED1, OLED2, OLED3 (refer to FIG. 5D) may be improved, and thus, the light emission efficiency of the display panel DP may be improved. A degree of improvement in light emission efficiency of the display panel DP may be more effective as a resolution of the display panel DP increases. Table 1 below shows a maximum increase rate (%) of the light emission efficiency according to a resolution (ppi) of the display panel that includes the refractive pattern PT in which three grooves HM are defined in the upper surface thereof per unit area having about 4 square micrometers, relative to a light emission efficiency of a display panel that includes a refractive pattern PT in which no groove is defined in an upper surface thereof.

TABLE 1

| | Maximum increase rate (%) of |
|---|---|
| Resolution (ppi) | light emission efficiency |
| 540 | 120 |
| 806 | 140 |
| 1200 | 160 |

Referring to Table 1, in case that two grooves HM per unit area of 4 square micrometers are defined in the upper surface U-P of the refractive pattern PT, the maximum increase rate of the light emission efficiency increases as the resolution increases. Accordingly, as the resolution increases, the increase rate of the light emission efficiency increases in case that the grooves HM are formed in the upper surface U-P of the refractive pattern PT. The window adhesive layer ADL may be disposed on the polarizer POL. The window adhesive layer ADL may have a refractive index equal to or smaller than about 1.5. A difference in refractive index between the window adhesive layer ADL and the cover layer CVL may be equal to or smaller than about 0.1. The window adhesive layer ADL may be disposed between the polarizer POL and the window WM, and the window WM may be attached to the polarizer POL by the window adhesive layer ADL.

Hereinafter, a manufacturing method of a display device will be described.

The display device manufactured by the manufacturing method of the disclosure is the same as the above-described display device DD (refer to FIG. 5D). Thus, details of the same elements described above will be omitted, and the same elements will be assigned with the same reference numerals.

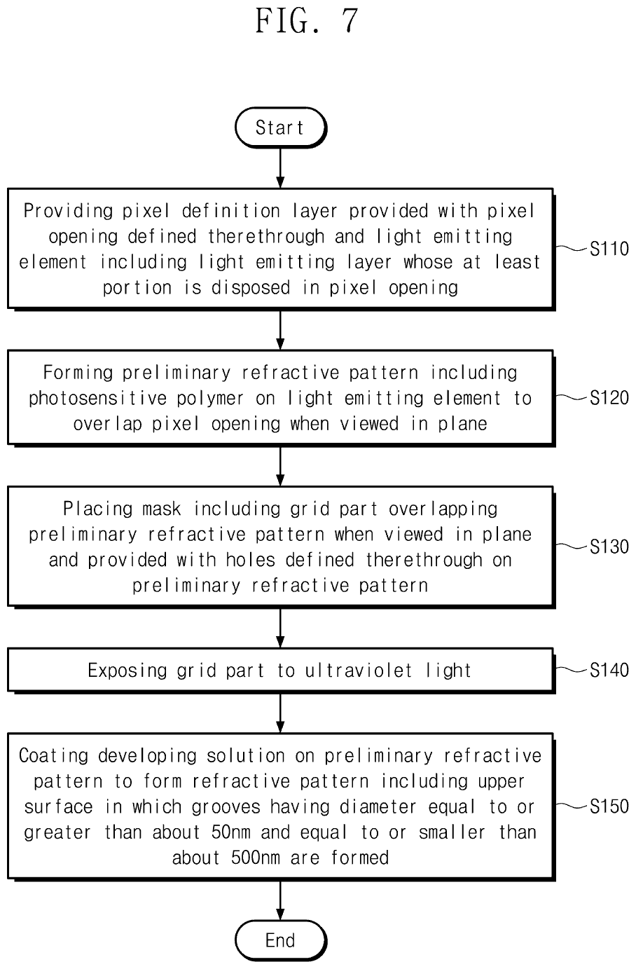

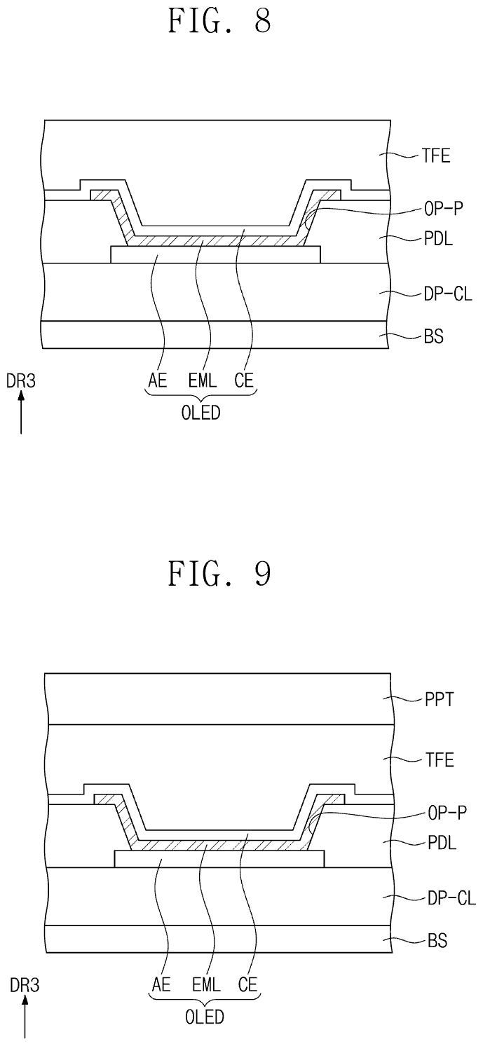

FIG. 7 is a flowchart illustrating the manufacturing method of the display device according to an embodiment of the disclosure. FIGS. 8 to 12 are cross-sectional views illustrating the manufacturing method of the display device according to an embodiment of the disclosure.

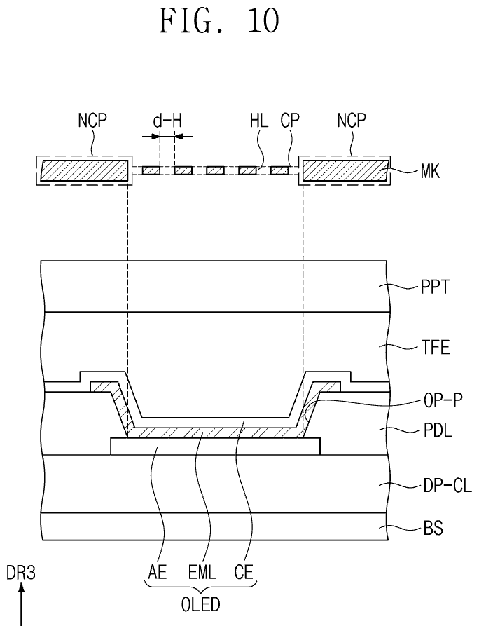

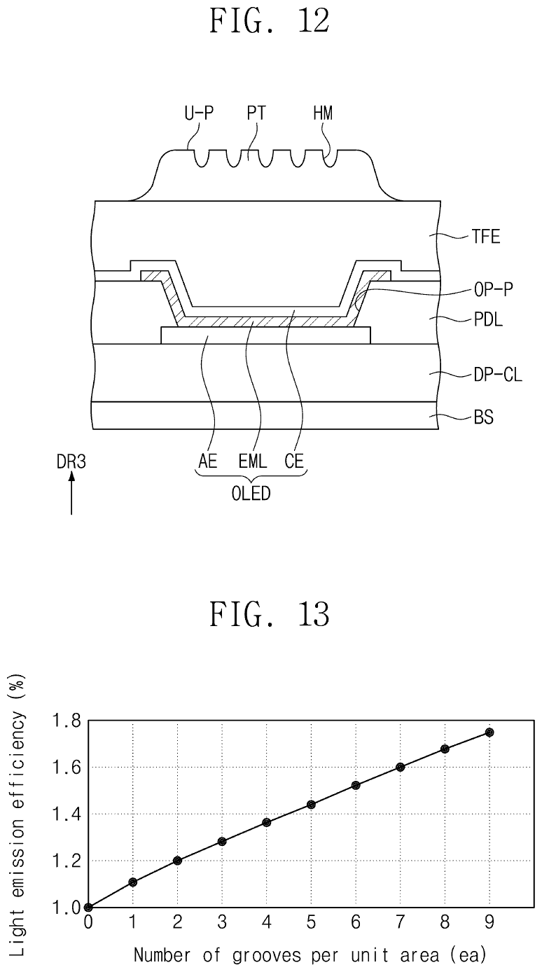

FIG. 9 is a schematic cross-sectional view illustrating a process of forming a preliminary refractive pattern PPT of the manufacturing method of the display device according to an embodiment of the disclosure. FIG. 10 is a schematic cross-sectional view illustrating a process of the manufacturing method of the display device, including placing a mask MK including a grid part CP through which holes HL are defined, according to an embodiment of the disclosure. FIG. 11 is a schematic cross-sectional view illustrating a process of irradiating an ultraviolet light UVL on the grid part CP of the manufacturing method of the display device according to an embodiment of the disclosure. FIG. 12 is a schematic cross-sectional view illustrating a process of forming the refractive pattern PT of the manufacturing method of the display device according to an embodiment of the disclosure.

Referring to FIG. 7, the manufacturing method of the display device may include providing the pixel definition layer with the pixel opening defined through the pixel definition layer and the light emitting element including the light emitting layer partially disposed in the pixel opening (S110). The manufacturing method also may include forming the preliminary refractive pattern including the photosensitive polymer on the light emitting element to overlap the pixel opening in a plan view (S120). The manufacturing method also may include placing the mask including the grid part overlapping the preliminary refractive pattern in a plan view, the mask provided with holes defined through the grid part on the preliminary refractive pattern (S130). The manufacturing method also may include exposing the grid part to the ultraviolet light (S140), and coating a developing solution on the preliminary refractive pattern to form the refractive pattern including the upper surface comprising grooves having a diameter equal to or greater than about 50 nm and equal to or smaller than about 500 nm (S150).

Referring to FIGS. 7 and 8, the providing of the light emitting element OLED including the pixel definition layer PDL provided with the pixel opening OP-P defined through the pixel definition layer PDL and the light emitting layer EML partially disposed in the pixel opening OP-P (S110) may include forming the encapsulation layer TFE on the second electrode CE.

Referring to FIGS. 7 and 9, in the forming of the preliminary refractive pattern PPT overlapping the pixel opening OP-P in a plan view and including the photosensitive polymer on the light emitting element OLED (S120), the preliminary refractive pattern PPT may include the block copolymer structural part. The preliminary refractive pattern PPT and the refractive pattern PT (refer to FIG. 12) may include a same material. The preliminary refractive pattern PPT may further include a monomer, photoinitiator, an additive, a solvent, or a combination thereof. As an example, the preliminary refractive pattern PPT may further include a radical photoinitiator or a positive ion photoinitiator. The preliminary refractive pattern PPT may have a physical property different from that of the refractive pattern PT (refer to FIG. 12). The refractive pattern PT (refer to FIG. 12) may have a hardness higher than that of the preliminary refractive pattern PPT. The preliminary refractive pattern PPT may be disposed on the light emitting element OLED. The preliminary refractive pattern PPT may be disposed on the encapsulation layer TFE. The preliminary refractive pattern PPT may be disposed directly on the encapsulation layer TFE.

Referring to FIGS. 7 and 10, in the placing of the mask MK including the grid part CP overlapping the preliminary refractive pattern PPT in a plan view and provided with the holes HL defined through the grid part CP on the preliminary refractive pattern PPT (S130), a distance d-H between a first hole and a second hole adjacent to the first hole among the holes HL may be equal to or greater than about 50 nm and equal to or smaller than about 500 nm in a plan view. The holes HL may completely penetrate the mask MK and may have a circular shape, a quadrangular shape, or a pentagonal shape in a plan view, or a combination thereof. The mask MK may include the grid part CP and a non-grid part NCP. The non-grid part NCP may be a part where the holes HL are not defined. The grid part CP may overlap the pixel opening OP-P in a plan view. The grid part CP may overlap the light emitting layer EML in a plan view.

Referring to FIGS. 7 and 11, in the exposing of the grid part CP to the ultraviolet light UVL (S140), the ultraviolet light UVL may be provided to the preliminary refractive pattern PPT through the grid part CP. The grid part CP may have a thickness smaller than a thickness of the non-grid part NCP. A degree of transmission of the ultraviolet light UVL in the grid part CP may be greater than a degree of transmission of the ultraviolet light UVL in the non-grid part NCP. The ultraviolet light UVL may be provided to the preliminary refractive pattern PPT through the hole HL or through a portion of the grid part CP where the hole HL is not defined. An exposure amount of the ultraviolet light UVL may be equal to or greater than about one Joule (1 J). As an example, the exposure amount of the ultraviolet light UVL may be about 3 J. In case that the exposure amount of the ultraviolet light UVL is smaller than about 1 J, the exposure amount of the ultraviolet light UVL may not be sufficient to cure the photosensitive polymer of the preliminary refractive pattern PPT, and thus, the groove HM (refer to FIG. 12) may not be formed. The diameter of the groove HM (refer to FIG. 12) formed by the exposure amount of the ultraviolet light UVL being greater than about 3 J may be substantially the same as the diameter of the groove HM (refer to FIG. 12) formed by the exposure amount of the ultraviolet light UVL being about 3 J.

Referring to FIGS. 7 and 12, in the coating of the developing solution on the preliminary refractive pattern to form the refractive pattern including the upper surface in which the grooves having the diameter equal to or greater than about 50 nm and equal to or smaller than about 500 nm are formed (S150), a portion of the preliminary refractive pattern PPT (refer to FIG. 11) to which the ultraviolet light UVL (refer to FIG. 11) is irradiated may be cured to form the refractive pattern PT after being treated with the developing solution. The number of grooves HM defined in the upper surface U-PT of the refractive pattern may be 3 or more and 9 or less per unit area. The unit area may be about 4 square micrometers.

The manufacturing method of the display device may further include forming the cover layer CVL (refer to FIG. 6) that covers the refractive pattern PT. The cover layer CVL has a refractive index smaller than the refractive index of the refractive pattern PT. The cover layer CVL may be formed after the coating of the developing solution on the preliminary refractive pattern PPT (refer to FIG. 11) that forms the refractive pattern PT (S150). The refractive pattern PT includes the upper surface in which the grooves HM have a diameter equal to or greater than about 50 nm and equal to or smaller than about 500 nm. The cover layer CVL (refer to FIG. 6) may cover the refractive pattern PT and may provide a flat surface.

Hereinafter, results of evaluating the light emission efficiency of the display device are explained in detail.

In order to evaluate the light emission efficiency of the display device of the present disclosure, the light control layer that includes the refractive pattern and the cover layer covering the refractive pattern was placed on a light emitting device emitting a constant light as a light source. The light emission efficiency was measured ten times while varying the number of grooves defined in the upper surface of the refractive pattern per unit area of 4 square micrometers from 0 (grooves not formed) to 9 grooves. The diameter of the groove was about 100 nm, the distance between the grooves was about 1 micrometer in a plan view, and the depth of the groove was about 105 nm.

FIG. 13 is a graph illustrating a variation of the light emission efficiency according to the number of the grooves per unit area.

Referring to FIG. 13, the graphs show the light emission efficiency in the cases where the number of the grooves was 1 to 9 in relative numbers based on the light emission efficiency setting as 1 in the case where no groove was formed. As the number of the grooves in the upper surface of the refractive pattern increases, the light emission efficiency was linearly increased and reached up to maximum of about 175% of the light emission efficiency. This is because the light generated by the light emitting layer is more likely in contact with the grooves as the number of the grooves formed in the upper surface of the refractive pattern increases and the light travels in substantially the same direction as the third direction after making contact with the grooves, thereby improving the light emission efficiency. However, in a case where the number of grooves is excessively large, the grooves may overlap each other, and as a result, the effect of increasing light emission efficiency may be reduced.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device comprising:
a pixel definition layer provided with a pixel opening defined through the pixel definition layer;
a light emitting element comprising a light emitting layer, at least a portion of the light emitting layer being disposed in the pixel opening;
a refractive pattern disposed on the light emitting element and overlapping the pixel opening; and
a cover layer covering the refractive pattern and having a refractive index smaller than a refractive index of the refractive pattern, wherein
a plurality of grooves is defined in an upper surface of the refractive pattern, and
each of the grooves has a diameter equal to or greater than about 50 nm and equal to or smaller than about 500 nm.

2. The display device of claim 1, wherein the refractive pattern further comprises a lower surface opposite to the upper surface and a side surface connecting the upper surface and the lower surface.

3. The display device of claim 2, wherein the side surface comprises a flat surface with a selectable inclination.

4. The display device of claim 1, wherein each of the grooves has a depth equal to or greater than about 50 nm and equal to or smaller than about 500 nm.

5. The display device of claim 1, wherein
the grooves are provided in three or more and nine or less per unit area of the upper surface, and
the unit area is about 4 square micrometers.

6. The display device of claim 1, wherein the refractive index of the refractive pattern is equal to or greater than about 1.6.

7. The display device of claim 1, wherein the refractive pattern comprises a photosensitive polymer.

8. The display device of claim 7, wherein the photosensitive polymer comprises a block copolymer structural part.

9. The display device of claim 1, wherein the refractive pattern has a thickness equal to or greater than about 0.5 micrometers and equal to or smaller than about 1.5 micrometers.

10. The display device of claim 1, wherein
the pixel opening comprises a first pixel opening, a second pixel opening, and a third pixel opening, having different sizes from each other, and
the refractive pattern comprises a first refractive pattern corresponding to the first pixel opening, a second refractive pattern corresponding to the second pixel opening, and a third refractive pattern corresponding to the third pixel opening.

11. The display device of claim 1, further comprising:
a polarizer disposed on the cover layer.

12. The display device of claim 1, further comprising:
an encapsulation layer disposed on the light emitting element,
wherein the refractive pattern is disposed on the encapsulation layer.

13. The display device of claim 12, further comprising:
an input sensor disposed between the light emitting element and the refractive pattern,
wherein the input sensor comprises:
a first insulating layer disposed on the encapsulation layer;
a first conductive layer disposed on the first insulating layer;
a second insulating layer disposed on the first insulating layer and covering the first conductive layer; and
a second conductive layer disposed on the second insulating layer, and the refractive pattern is disposed on the second insulating layer.

14. The display device of claim 13, wherein
the input sensor further comprises a third insulating layer covering the second conductive layer and disposed on the second insulating layer, and
the refractive pattern is disposed on the third insulating layer.

15. A method of manufacturing a display device, comprising:
providing a pixel definition layer provided with a pixel opening defined through the pixel definition layer and a light emitting element comprising a light emitting layer, at least a portion of the light emitting layer being disposed in the pixel opening;
forming a preliminary refractive pattern comprising a photosensitive polymer on the light emitting element to overlap the pixel opening in a plan view;
placing a mask comprising a grid part overlapping the preliminary refractive pattern in a plan view and provided with a plurality of holes defined through the grid part on the preliminary refractive pattern;
exposing the grid part to an ultraviolet light; and
coating a developing solution on the preliminary refractive pattern to form a refractive pattern comprising an upper surface in which a plurality of grooves having a diameter equal to or greater than about 50 nm and equal to or smaller than about 500 nm is formed.

16. The method of claim 15, wherein an exposure amount of the ultraviolet light is equal to or greater than about one Joule (1 J).

17. The method of claim 15, wherein a distance between a first hole and a second hole adjacent to the first hole among the holes is equal to or greater than about 50 nm and equal to or smaller than about 500 nm.

18. The method of claim 15, wherein the photosensitive polymer comprises a block copolymer structural part.

19. The method of claim 15, further comprising:
forming a cover layer covering the refractive pattern and having a refractive index smaller than a refractive index of the refractive pattern.

20. The method of claim 15, wherein
the grooves are provided in three or more and nine or less per unit area of the upper surface, and
the unit area is about 4 square micrometers.
